(19) United States
(12) Patent Application Publication
(10) Pub. No.: US 2013/0057228 A1
(43) Pub. Date: Mar. 7, 2013

(54) METHOD FOR MONITORING THE FUNCTION OF A ROTATING ELECTRIC MACHINE AND MONITORING SYSTEM FOR CARRYING OUT SAID METHOD

(71) Applicants: Thomas Kunz, Ennetbaden (CH); Alexander Schwery, Kuttigen (CH)

(72) Inventors: Thomas Kunz, Ennetbaden (CH); Alexander Schwery, Kuttigen (CH)

(73) Assignee: ALSTOM TECHNOLOGY LTD, Baden (CH)

(21) Appl. No.: 13/603,129

(22) Filed: Sep. 4, 2012

Related U.S. Application Data
(63) Continuation of application No. PCT/EP2011/052221, filed on Feb. 15, 2011.

(30) Foreign Application Priority Data
Mar. 8, 2010 (DE) 102010010600.3

(51) Int. Cl. G01R 31/34

(52) U.S. Cl. 322/99

(57) ABSTRACT

A method is provided for monitoring the function of a rotating electric machine, operating between 20 and 500 MVA, which includes a rotor, surrounded concentrically by a stator, the rotor and the stator having rotor and stator lamination elements made from sheets layered and pressed in the axial direction to form a composite and pressed by electrically insulated tension bolts passing through the rotor and stator lamination elements in the axial direction and insulated with respect to the lamination elements. Simple and reliable monitoring of the insulation of the tension bolts is achieved since the tension bolt insulation is electrically measured continuously during operation of the machine, the tension bolts each being set to a predetermined potential with respect to the associated lamination element by a voltage source, and the current flow through the voltage source and/or through the respective tension bolt being measured and evaluated.

### CROSS REFERENCE TO RELATED APPLICATIONS

This application is a continuation of International Patent Application No. PCT/EP2011/052221, filed Feb. 15, 2011, which claims priority to German Patent Application No. 102010010600.3, filed Mar. 8, 2010, the entire contents of all of which are incorporated herein by reference as if fully set forth.

### FIELD OF THE INVENTION

The present invention relates to the field of rotating electric machines. It relates to a method for monitoring the function of a rotating electric machine, in particular a dual-feed asynchronous machine in the power range between 20 MVA and 500 MVA. The invention also relates to a monitoring system for carrying out said method.

### BACKGROUND

Dual-feed asynchronous machines in the power range from 20 MVA to 500 MVA can be used for the variable-speed production of energy. These machines are distinguished by a distributed three-phase winding on the rotor. The rotor winding comprises individual rods which are embedded in grooves in the rotor lamination pack. In the winding head, the individual rods are connected to a winding. The current is fed in via at least three slip rings, which are fixed to the shaft at the end of the machine. A detail from such a machine is reproduced in highly simplified form in FIG. 1. The asynchronous machine 10 illustrated in FIG. 1 has a machine axis 13. Rotatable about this axis 13 is a central body 11 having a shaft, on which the slip rings 12 are arranged. Arranged around the central body 11 is the rotor lamination element 14, which, under a winding head 16 of the rotor winding, is adjoined by an auxiliary rim 20. The rotor lamination element 14 is surrounded concentrically by a stator lamination element 15, in which there is accommodated a stator winding which, at the end of the element, projects outward with a stator winding head 17. The rotor lamination element 14 is reproduced in an enlarged detail in FIG. 2.

Since the rotors of dual-feed asynchronous machines carry a rotor winding 18, the latter has to be secured against the centrifugal forces that occur. The rotor lamination pack is used firstly to absorb these forces and, at the same time, defines the path of the magnetic flux. The auxiliary rim 20 is used to absorb the centrifugal forces which act on the rotor winding head 16. The auxiliary rim 20 and also the rotor lamination element 14 comprise layered sheets which are pressed in the axial direction to form a composite. It is known to use a pressure plate 19 here, which distributes the pressure applied by the tension bolts 21 or shear bolts 22 to the sheets of the rotor lamination pack (see, for example, DE-A1-195 13 457 or DE-A1-10 2007 000 668). Similar conditions also apply in the stator lamination element 15.

Various demands are made on the rotor lamination element 14. In FIG. 2, the basic subdivision into an electric region 14a and a mechanical region 14b is illustrated. Firstly, there should be sufficient axial pressure in the teeth between the layers of the sheets to guarantee the homogeneity of the element. In order to avoid vibrations, the layers must not loosen, since relative movements between the teeth and rotor winding 18 could damage the insulation. Secondly, the pressure must not be too high, in order to avoid damage to the insulating layers between the individual sheets, since such damage would lead to increased losses.

The tension bolts in the stator or rotor are located in the magnetically active part of the respective lamination element. During the operation of the motor generator, the basic wave of the magnetic flux sweeps over the tension bolts in the stator at the nominal frequency. The tension bolts 21 in the rotor of the dual-feed asynchronous machine are swept over at slip frequency during operation. During the running-up phase, on the other hand, the rotor of the asynchronous machine, and therefore the tension bolts 21 on the rotor, “see” the nominal frequency.

As a result of the changing flux which sweeps over the bolts, a voltage is induced in the latter. Were the bolts to be in direct contact with the lamination element, high currents would flow via the bolts. In order to prevent these currents, the bolts are fixed in the holes of the stator and rotor respectively by insulators, or they are insulated over the entire length. The potential of the bolts is thus not defined. During the installation of the machine, the insulation of each bolt with respect to the lamination element is carefully checked. Only if all the bolts are sufficiently well insulated with respect to the lamination elements can the machine be started up. The insulation of the bolts is inspected again at defined intervals in the context of maintenance work. In this case, hitherto, the machine had to be out of operation.

During operation, over time dirt can collect at the passages of the bolts through the ventilation ducts. This leads to creeping currents. If the dirt contains metallic particles, it is possible for electrically conductive contacts between bolts and lamination body to occur. Should more than one contact occur on one or different bolts, high currents flow, which can lead to great damage to the machine. For this reason, there is an interest in monitoring the insulation of the bolts during operation as well.

In principle, it would be possible to measure the induced voltage on the bolt. If an undesired current flows via the bolts, this could theoretically be detected by a change in the applied voltage. In practice, however, the voltage change in the case of small currents will be so small that this idea can only be implemented poorly in practice.

### SUMMARY

The present disclosure is directed to a method for monitoring the function of a rotating electric machine in a power range between 20 MVA and 500 MVA. The machine including a rotor rotating about an axis and surrounded concentrically by a stator, the rotor and the stator having a rotor lamination element and a stator lamination element, respectively, built up from sheets layered and pressed in an axial direction to form a composite and pressed by means of electrically insulated tension bolts passing through the rotor lamination element and stator lamination element in the axial direction and insulated with respect to the lamination elements. The method includes continuously measuring the insulation of the tension bolts in an electrical way during operation of the machine. The tension bolts each being set to a predetermined potential with respect to the associated lamination element by a voltage source. The method also includes measuring and evaluating the current flow through the voltage source and/or through the respective tension bolt.

The disclosure is also directed to a monitoring system for carrying out the above method. The monitoring system includes a voltage source which is connected to the lamination elements and to the tension bolts. Devices that measure the current flowing through the tension bolts are provided and are connected to a monitoring unit.

### BRIEF DESCRIPTION OF THE DRAWINGS

The invention is to be explained in more detail below by using exemplary embodiments in conjunction with the drawing, in which:

FIG. 1 shows a highly simplified illustration of a detail from an asynchronous machine which is suitable for the application of the invention;

FIG. 2 shows an enlarged detail of the structure of the rotor lamination element of the machine from FIG. 1 including a pressure plate used to tension the rotor lamination element and having various bolts according to an exemplary embodiment of the invention; and

FIG. 3 shows a highly simplified block diagram of a monitoring system for monitoring the tension bolt insulation according to an exemplary embodiment of the invention.

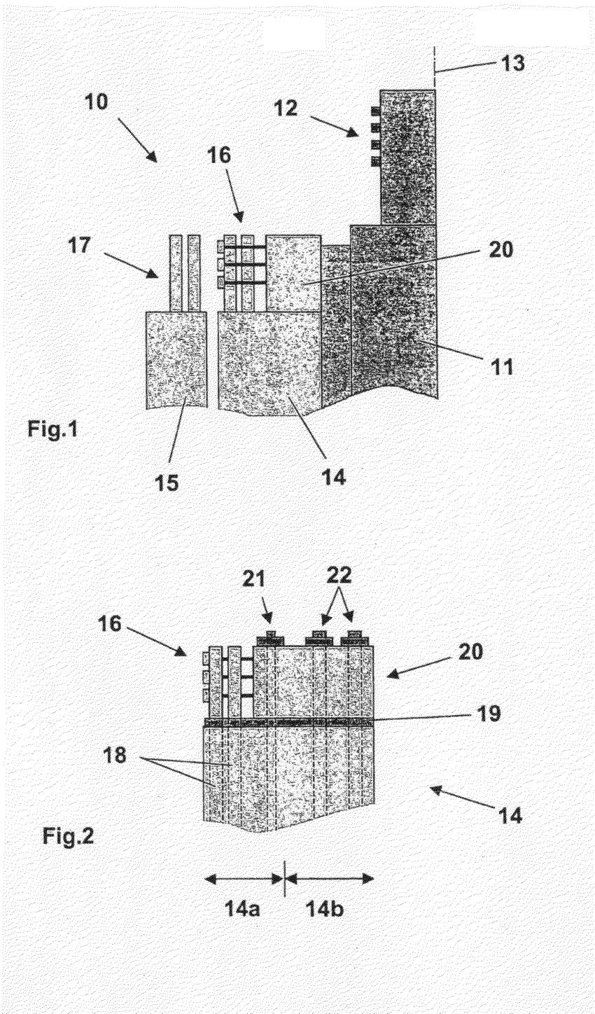

### DETAILED DESCRIPTION OF THE PREFERRED EMBODIMENTS

### Introduction to the Embodiments

It is therefore an object of the invention to devise a method for monitoring the function of a rotating electric machine with which the insulation of the tension bolts in the stator and/or rotor lamination element can be monitored in a straightforward way during the operation of the machine, and to specify a monitoring system for carrying out said method.

The object is achieved as set forth in the appended claims.

It is preferable that the insulation of the tension bolts is measured continuously in an electrical way during operation of the machine, the tension bolts each being set to a predetermined potential with respect to the associated lamination element by means of a voltage source, and the current flow through the voltage source and/or through the respective tension bolt being measured and evaluated.

In one refinement of the method according to the invention, if predefined values of the current through the tension bolt or bolts are exceeded, an alarm and possibly an emergency stop of the machine is triggered. Here, the voltage source used can be a pure DC voltage source.

However, it is also conceivable to use a DC voltage source with superimposed alternating voltage as voltage source.

The monitoring system according to the invention has a voltage source which is connected to the lamination elements and to the tension bolts, and in that means for measuring the current flowing through the tension bolts are provided and are connected to a monitoring unit.

In particular, the means for measuring the current flowing through the tension bolts comprise current sensors which are inserted into the circuit formed from voltage source, tension bolt and lamination element.

All the tension bolts to be monitored can be connected to a common voltage source. However, it is also conceivable for each tension bolt to be monitored to be assigned a dedicated current sensor, and for the currents measured by the current sensors to be evaluated in the monitoring unit.

In one refinement of the monitoring system, an alarm indicator is connected to the output side of the monitoring unit. However, the output side of the monitoring unit can also be connected to a machine control system for controlling the rotating electric machine.

In principle, the voltage source can be formed as a pure DC voltage source. However, it is also conceivable for the voltage source to be formed as a DC voltage source with superimposed alternating voltage.

### DETAILED DESCRIPTION

A central idea of the monitoring according to the present invention includes

fixing the floating potential of the tension bolts via a clearly defined voltage source. To this end, each bolt is connected to a voltage source which sets the potential either to a defined DC voltage or else to a DC voltage with a superimposed alternating voltage. Monitoring the current which flows through the voltage source can trigger an alarm or emergency stop of the machine if predefined values are exceeded. It is possible to monitor the current in each individual tension bolt or else of all bolts together.

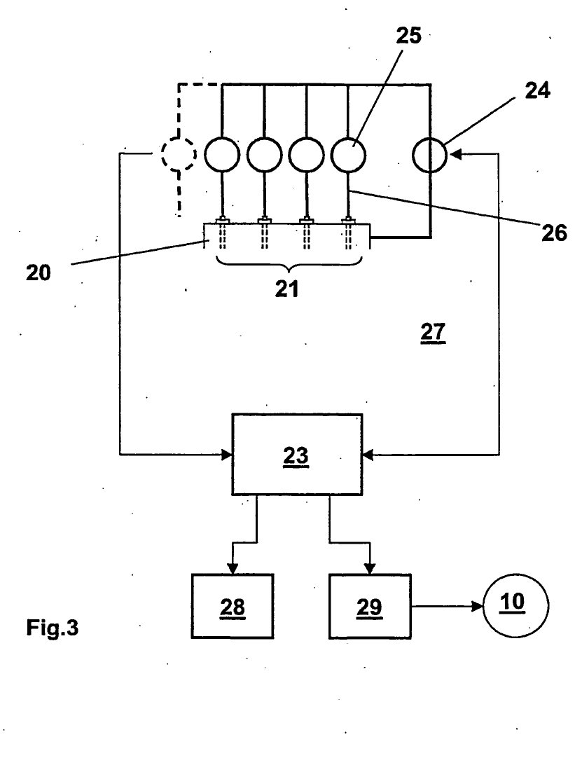

A corresponding monitoring system is reproduced in FIG. 3 by using the example of the tension bolts 21 of the rotor. The ends of the tension bolts 21 of the rotor projecting out of the auxiliary rim 20, according to the exemplary embodiment shown in FIG. 3, are each connected to one pole of a voltage source 24. The other pole of the voltage source 24 is connected to the auxiliary rim 20 itself or to the rotor lamination element. In this way, for each of the tension bolts 21, a circuit 26 is defined which is then more or less completed when the insulation between tension bolt 21 and lamination element is more or less highly restricted.

In the case of a predefined voltage on the voltage source 24, the current flowing through the circuits 26 is a measure of the condition of the insulation. It is then possible to define a current value at which, when exceeded, either a warning or an alarm is output or alternatively, the machine is stopped directly. If a current sensor 25 is inserted into each of the circuits 26, the condition of the insulation on each tension bolt 21 can be determined and monitored separately, by the current in the respective circuit 26 being measured and evaluated. This results in the possibility, in the event of a repair, of focusing specifically on the bolts which have indicated the highest current in their circuit.

However, it is also conceivable to measure only the current through the voltage source 24, which represents the sum of the currents in the individual circuits 26 and, accordingly, reports about the global condition of the insulation of all the tension bolts 21 together. In the event of a repair, it is then necessary to determine separately which of the tension bolts 21 are substantially responsible for the measured current.

In principle, the voltage source 24 used can be a pure DC source. In order to avoid or to suppress interferences, however, it may be advantageous to superimpose an alternating voltage on the DC voltage, which then permits an alternating voltage measurement with the corresponding advantages.

In order to control and monitor the voltage source 24, the latter is connected to a central monitoring unit 23, which at the same time accepts and evaluates the measured values from the current sensors 25. Connected to one output of the monitoring unit 23 is an (acoustic or optical) alarm indicator 28 which, when a preset value of the measured currents is exceeded, outputs an alarm. Another output of the monitoring unit 23 is optionally connected to the machine control system 29 which, in such a case or when a higher limiting value is exceeded, carries out an emergency stop, which brings the machine to a standstill in order to avoid greater damage.

The level of the impressed voltage and the limiting values for the measured current depend to a great extent on the details of the construction of the lamination element and the insulation of the tension bolts and must be matched to the respective conditions.

It is understood, therefore, that this invention is not limited to the particular embodiments disclosed, but is intended to cover all modifications which are within the spirit and scope of the invention as defined by the appended claims; the above description; and/or shown in the attached drawings.

### LIST OF DESIGNATIONS

10 Asynchronous machine
11 Central body (with shaft)
12 Slip ring
13 Axis
14 Rotor lamination element
14a Electric region
14b Mechanical region
15 Stator lamination element
16 Rotor winding head
17 Stator winding head
18 Rotor winding
19 Pressure plate
20 Auxiliary rim
21 Tension bolt
22 Shear bolt
23 Monitoring unit
24 Voltage source
25 Current sensor
26 Circuit
27 Monitoring system
28 Alarm indicator
29 Machine control system

What is claimed is:

1. A method for monitoring the function of a rotating electric machine (10) in a power range between 20 MVA and 500 MVA, the machine comprising a rotor (11, 14) rotating about an axis (13) and surrounded concentrically by a stator (15, 17), the rotor (11, 14) and the stator (15, 17) having a rotor lamination element (14) and a stator lamination element (15) respectively built up from sheets layered and pressed in an axial direction to form a composite and pressed by means of electrically insulated tension bolts (21) passing through the rotor lamination element (14) and stator lamination element (15) in the axial direction and insulated with respect to the lamination elements (14, 15), the method comprising:
measuring continuously the insulation of the tension bolts in an electrical way during operation of the machine, the tension bolts (21) each being set to a predetermined potential with respect to the associated lamination element (14 or 15) by a voltage source (24); and
measuring and evaluating the current flow through the voltage source (24) and/or through the respective tension bolt (21).

2. The method as claimed in claim 1, wherein if predefined values of the current through the tension bolt or bolts (21) are exceeded, an alarm and/or an emergency stop of the machine is triggered.

3. The method as claimed in claim 1, wherein the voltage source (24) used is a pure DC voltage source.

4. The method as claimed in claim 1, wherein the voltage source (24) used is a DC voltage source with superimposed alternating voltage.

5. The method as claimed in claim 1, wherein the electric machine (10) is a dual-feed asynchronous machine.

6. A monitoring system (27) for carrying a method for monitoring the function of a rotating electric machine (10) in a power range between 20 MVA and 500 MVA, the machine comprising a rotor (11, 14) rotating about an axis (13) and surrounded concentrically by a stator (15, 17), the rotor (11, 14) and the stator (15, 17) having a rotor lamination element (14) and a stator lamination element (15) respectively built up from sheets layered and pressed in an axial direction to form a composite and pressed by means of electrically insulated tension bolts (21) passing through the rotor lamination element (14) and stator lamination element (15) in the axial direction and insulated with respect to the lamination elements (14, 15), the method comprising:
measuring continuously the insulation of the tension bolts in an electrical way during operation of the machine, the tension bolts (21) each being set to a predetermined potential with respect to the associated lamination element (14 or 15) by a voltage source (24); and
measuring and evaluating the current flow through the voltage source (24) and/or through the respective tension bolt (21), the monitoring system comprising a voltage source (24) which is connected to the lamination elements (14, 15) and to the tension bolts (21), and devices (25) that measure the current flowing through the tension bolts (21) are provided and are connected to a monitoring unit (23).

7. The monitoring system as claimed in claim 6, wherein the devices for measuring the current flowing through the tension bolts (21) comprise current sensors (25) which are inserted into the circuit formed from voltage source (24), tension bolt (21) and lamination element (14, 15).

8. The monitoring system as claimed in claim 6, wherein all the tension bolts (21) to be monitored are connected to a common voltage source (24).

9. The monitoring system as claimed in claim 7, wherein each tension bolt (21) to be monitored is assigned a dedicated current sensor (25), and in that the currents measured by the current sensors (25) are evaluated in the monitoring unit (23).

10. The monitoring system as claimed in claim 6, wherein an alarm indicator (28) is connected to an output side of the monitoring unit (23).

11. The monitoring system as claimed in claim 6, wherein an output side of the monitoring unit (23) is connected to a machine control system (29) for controlling the rotating electric machine (10).

12. The monitoring system as claimed in claim 6, wherein the voltage source (24) is formed as a pure DC voltage source.

13. The monitoring system as claimed in claim 6, wherein the voltage source (24) is formed as a DC voltage source with superimposed alternating voltage.
